(19) United States
(12) Patent Application Publication
(10) Pub. No.: US 2026/0047253 A1
(43) Pub. Date: Feb. 12, 2026

(54) DISPLAY DEVICE AND ELECTRONIC DEVICE INCLUDING THE SAME

(71) Applicant: Samsung Display Co., Ltd., Yongin-si (KR)

(72) Inventors: HYUNGKEUN PARK, Yongin-si (KR); JONGHYEON LEE, Yongin-si (KR); WONJI GU, Yongin-si (KR); HYUNDO SHIN, Yongin-si (KR); MIN-KYU YEO, Yongin-si (KR); CHANYOUNG LIM, Yongin-si (KR)

(21) Appl. No.: 19/234,040

(22) Filed: Jun. 10, 2025

(30) Foreign Application Priority Data
Aug. 9, 2024 (KR) 10-2024-0106493

(51) Int. Cl. H10H 29/41; H10H 29/80; H10H 29/856

(52) U.S. Cl. CPC H10H 29/41; H10H 29/8321; H10H 29/856

(57) ABSTRACT

Provided is a display device including a complementary metal-oxide-semiconductor (CMOS) wafer having a display region which has unit regions and a boundary region, a light-emitting element layer on the CMOS wafer and having light-emitting diodes and a planarization layer that covers the light-emitting diodes, an auxiliary electrode connected to light-emitting elements and provided in the planarization layer, and a common electrode on the planarization layer and connected to the auxiliary electrode. The planarization layer includes a trench which overlaps the boundary region and a portion of which is recessed in a direction from an upper surface of the planarization layer toward the CMOS wafer, and the auxiliary electrode is provided in the trench and has a reversed trapezoidal shape on a cross section.

### CROSS-REFERENCE TO RELATED APPLICATION

The present application claims priority to and the benefit of Korean Patent Application No. 10-2024-0106493, filed on Aug. 9, 2024, in the Korean Intellectual Property Office, the entire content of which is hereby incorporated by reference.

### BACKGROUND

Embodiments of the present disclosure herein relate to a display device, and, for example, to a display device including a CMOS wafer and a light-emitting diode, and an electronic device including the same.

Electronic apparatuses, which provide an image to a user, such as smartphones, laptop computers, car navigation systems and smart televisions, include a display device to display an image. Augmented reality devices, virtual reality devices, and video projection devices may include a micro display device. The micro display device may include a CMOS wafer and a light-emitting diode on the CMOS wafer so as to display an image having high luminance while being driven at low power.

### SUMMARY

Embodiments of the present disclosure provide a display device in which light loss is reduced, and defects are reduced.

An embodiment of the present disclosure provides a display device including a complementary metal-oxide-semiconductor (CMOS) wafer including a display region which has unit regions and a boundary region having a grid shape and provided between the unit regions, and a non-display region which is adjacent to the display region; a light-emitting element layer on the CMOS wafer, and including light-emitting diodes that overlap the unit regions and a planarization layer that covers the light-emitting diodes; an auxiliary electrode connected to light-emitting elements and on the planarization layer; and a common electrode connected to the auxiliary electrode and on the planarization layer, wherein the planarization layer includes a trench which overlaps the boundary region and a portion of which is recessed from an upper surface of the planarization layer toward the CMOS wafer, and the auxiliary electrode is provided in the trench and has a reversed trapezoidal shape on a cross section.

In an embodiment, the auxiliary electrode may include an upper portion adjacent to the upper surface of the planarization layer, a lower portion opposed to the upper portion, and a side portion that connects the upper portion and the lower portion, and an angle between the side portion and a virtual line that extends from the lower portion may be about 60 degrees to about 89 degrees.

In an embodiment, a width of the upper portion may be about 0.5 μm to about 1.0 μm, and a width of the lower portion may be about 0.3 μm to about 0.7 μm.

In an embodiment, a thickness from the upper portion to the lower portion may be about 0.5 μm to about 1.7 μm.

In an embodiment, a surface of the upper portion may be uneven.

In an embodiment, the upper portion may have a shape which is concave in a direction from the upper portion toward the lower portion.

In an embodiment, the display device may further include a barrier pattern provided in the trench and that covers the lower portion and the side portion, and the barrier pattern may have conductivity (e.g., electrical conductivity).

In an embodiment, the light-emitting diodes may each include a first electrode structure on the CMOS wafer and connected to a transistor included in the CMOS wafer; a light-emitting layer on the first electrode structure; and a second electrode structure on the light-emitting layer.

In an embodiment, at least any one of the first electrode structure or the light-emitting layer may have a trapezoidal shape on a cross section, and the second electrode structure may cover at least a portion of an upper surface or a side surface of the light-emitting layer.

In an embodiment, the first electrode structure may include a metal layer; a reflection layer on the metal layer; a first barrier layer between the metal layer and the reflection layer; a first transparent conductive oxide layer on the reflection layer; and a second barrier layer between the reflection layer and the first transparent conductive oxide layer.

In an embodiment, the metal layer may include any one among gold (Au), copper (Cu), silver (Ag), tin (Sn), titanium (Ti), zirconium (Zr), and tantalum (Ta), and/or may include an alloy of two metals thereof.

In an embodiment, on a cross section, the auxiliary electrode may be between the adjacent first electrode structures.

In an embodiment, the first barrier layer and the second barrier layer may each include a barrier metal nitride layer.

In an embodiment, the first electrode structure may further include a third barrier layer under the metal layer, and the third barrier layer may include titanium nitride and/or tantalum nitride.

In an embodiment, the second electrode structure may include a transparent conductive oxide layer.

In an embodiment, the CMOS wafer may include a silicon substrate in which source and/or drain regions are defined; a gate on the silicon substrate; a first insulation layer on the silicon substrate and that covers the gate; a first contact electrode connected to the source or drain regions through a first contact hole defined in the first insulation layer; a second insulation layer on the first insulation layer and that covers the first contact electrode; and a second contact electrode connected to a first metal structure and connected to the first contact electrode through a second contact hole that passes through the second insulation layer.

In an embodiment, the display device may further include a side insulation layer which covers the light-emitting diodes, and side reflection layers which cover the side insulation layer that overlap the light-emitting diodes and are spaced apart from each other on the side insulation layer.

In an embodiment, the common electrode may be in contact with the light-emitting diode through a contact hole that overlaps the light-emitting diode and that penetrates from the planarization layer to the side reflection layer and the side insulation layer.

In an embodiment, the display device may further include a passivation layer on the common electrode, and the passivation layer may include an inorganic material.

In an embodiment, the planarization layer may include an inorganic material.

According to one or more embodiments, an electronic device may include the display device, wherein the electronic device may be one selected from among a flat panel display, a curved display, a computer monitor, a medical monitor, a television, a billboard, an indoor light, an outdoor light, a signal light, a head-up display, a fully transparent display, a partially transparent display, a flexible display, a rollable display, a foldable display, a stretchable display, a laser printer, a telephone, a mobile phone, a tablet, a phablet, a personal digital assistant (PDA), a wearable device, a laptop computer, a digital camera, a camcorder, a viewfinder, a micro display, a 3D display, a virtual reality display, an augmented reality display, a vehicle, a video wall including a plurality of displays tiled together, a theater screen, a stadium screen, a phototherapy device, and a signboard.

### BRIEF DESCRIPTION OF THE DRAWINGS

The accompanying drawings are included to provide a further understanding of subject matter of the present disclosure, and are incorporated in and constitute a part of this specification. The drawings illustrate embodiments of the present disclosure and, together with the description, serve to explain principles of the present disclosure. In the drawings:

FIG. 1 is a perspective view of a display device according to an embodiment of the present disclosure;

FIG. 2 illustrates a cross section of the display device illustrated in FIG. 1 as an example;

FIG. 3A is a plan view in which a common electrode according to an embodiment of the present disclosure is provided in a display region and a non-display region of a display device;

FIG. 3B is a plan view illustrating an arrangement relationship of a voltage transfer electrode, auxiliary electrodes, and a common electrode according to an embodiment of the present disclosure;

FIG. 4A is an enlarged plan view illustrating a partial region of a display region in FIG. 3A;

FIG. 4B is a cross-sectional view taken along line I-I′ of FIG. 4A;

FIG. 4C is an enlarged cross-sectional view of a portion of an auxiliary electrode in FIG. 4B;

FIGS. 5A and 5B are detailed cross-sectional views illustrating a first electrode structure in FIG. 4B;

FIG. 6 is a detailed cross-sectional view illustrating a light-emitting diode in FIG. 4B;

FIG. 7A is an enlarged plan view illustrating a partial region of a non-display region in FIG. 4A;

FIG. 7B is a cross-sectional view taken along line II-II′ of FIG. 7A;

FIG. 8A is a cross-sectional view illustrating a region corresponding to the region in FIG. 4B;

FIG. 8B is a cross-sectional view illustrating a portion of an auxiliary electrode according to an embodiment of the present disclosure;

FIG. 8C is a cross-sectional view illustrating a portion of an auxiliary electrode according to an embodiment of the present disclosure; and

FIGS. 9A to 9E are cross-sectional views illustrating a method of manufacturing a display device according to an embodiment of the present disclosure.

### DETAILED DESCRIPTION

In this specification, it will be understood that when an element (or a region, a layer, a portion, or the like) is referred to as being “on”, “connected to” or “coupled to” another element, it can be directly on/connected to/coupled to the other element or layer or intervening elements may be therebetween.

Like numerals or symbols refer to like elements throughout. Also, in the drawings, the thicknesses, ratios, and dimensions of the elements may be exaggerated for effective description of the technical contents. The term “and/or” includes all of one or more combinations which can be defined by related elements.

Although the terms first, second, and/or the like may be used to describe various elements, these elements should not be limited by these terms. These terms are only used to distinguish one element from another element. For example, a first element may be referred to as a second element, and similarly, a second element may also be referred to as a first element without departing from the scope of the present disclosure. The singular forms include the plural forms as well, unless the context clearly indicates otherwise.

Also, terms of “below”, “on lower side”, “above”, “on upper side”, or the like may be used to describe the relationships of the elements illustrated in the drawings. These terms are relative concepts and are described on the basis of the directions indicated in the drawings.

It will be understood that the term “includes” or “comprises”, when used in this specification, specifies the presence of stated features, integers, steps, operations, elements, components, or a combination thereof, but does not preclude the presence or addition of one or more other features, integers, steps, operations, elements, components, or combinations thereof.

Unless otherwise defined, all terms (including technical and scientific terms) used herein have the same meaning as commonly understood by one of ordinary skills in the art to which the present disclosure belongs. Also, terms, such as those defined in commonly used dictionaries, should be interpreted as having a meaning that is consistent with their meaning in the context of the relevant art and should not be interpreted in an idealized or overly formal sense unless expressly so defined herein.

Hereinafter, embodiments of the present disclosure will be described with reference to the accompanying drawings.

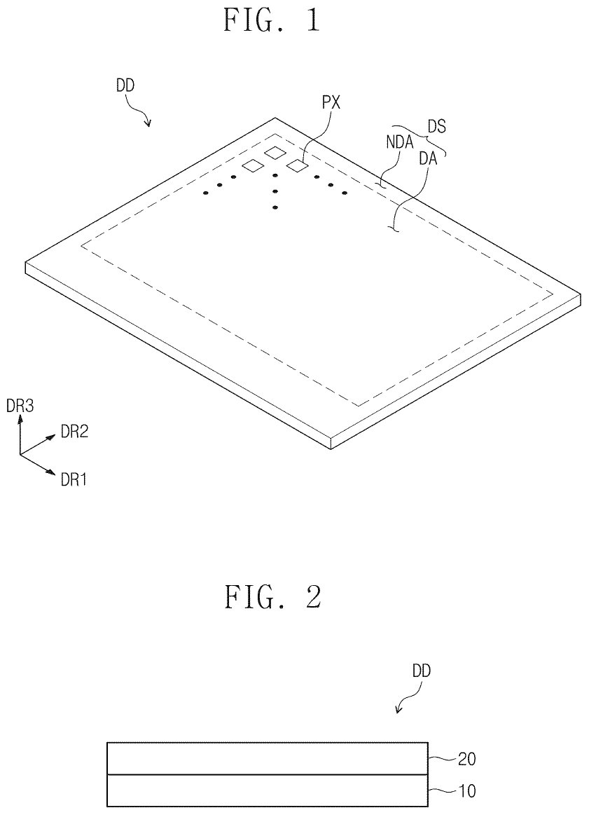

FIG. 1 is a perspective view of a display device according to an embodiment of the present disclosure.

Referring to FIG. 1, a display device DD according to an embodiment of the present disclosure may have a rectangular shape having long sides extending in a first direction DR1, and short sides extending in a second direction DR2 crossing the first direction DR1. However, an embodiment of the present disclosure is not limited thereto, and the display device DD may have various suitable shapes such as a circular or polygonal shape. Hereinafter, a direction substantially perpendicularly crossing a plane defined by the first direction DR1 and the second direction DR2 is defined as a third direction DR3. In this specification, the wording “when viewed on a plane” is defined as being in a state viewed in the third direction DR3.

An upper surface of the display device DD may be defined as a display surface DS, and may have a plane defined by the first direction DR1 and the second direction DR2. Images IM generated in the display device DD may be provided to a user through the display surface DS.

The display surface DS may include a display region DA and a non-display region NDA around the display region DA. The display region DA displays an image, and the non-display region NDA does not display an image. The non-display region NDA may surround the display region DA. However, an embodiment of the present disclosure is not limited thereto, and the non-display region NDA may not be provided at one side of the display region DA.

A plurality of pixels PX may be provided in the display region DA. The pixels PX may be provided in a matrix form. The pixels PX may each include a pixel circuit and a light-emitting diode. The pixels PX may all generate light of the same color. In an embodiment of the present disclosure, the pixels PX may include a plurality of groups that generate light of different colors.

FIG. 2 illustrates a cross section of the display device illustrated in FIG. 1 as an example.

Referring to FIG. 2, the display device DD may include a circuit element layer 10 and a light-emitting element layer 20. However, an embodiment of the present disclosure is not limited thereto, and another functional layer such as a lens layer on the light-emitting element layer 20 may be added to the display device DD according to an embodiment of the present disclosure.

The circuit element layer 10 may include a pixel circuit. The pixel circuit may control an operation of a light-emitting diode of the light-emitting element layer 20 to be further described herein. The pixel circuit may include at least one transistor. The circuit element layer 10 may include a complementary metal-oxide-semiconductor (CMOS) wafer. The CMOS wafer may include an nMOSFET (NMOS) and a pMOSFET (PMOS) which are complementarily connected. A plurality of pixel regions are regularly provided on the CMOS wafer, and the pixel circuit is provided in each pixel region.

The light-emitting element layer 20 may include a light-emitting diode electrically connected to the pixel circuit. The light-emitting diode, which is a type (or kind) of compound semiconductors, is an electrically driven light-emitting diode containing gallium (Ga), phosphorus (P), and arsenic (As) as main semiconductor materials. When a forward current is applied to a p-n junction structure, electrons and holes may be combined at a junction surface to generate light of a set or particular wavelength corresponding to a bandgap energy.

According to an embodiment, the lens layer may be on the light-emitting element layer 20, and may include a lens. The lens may be provided to correspond to the light-emitting diode. The lens condenses light emitted from the light-emitting diode. The light condensed through the lens may be transmitted through a light guide unit.

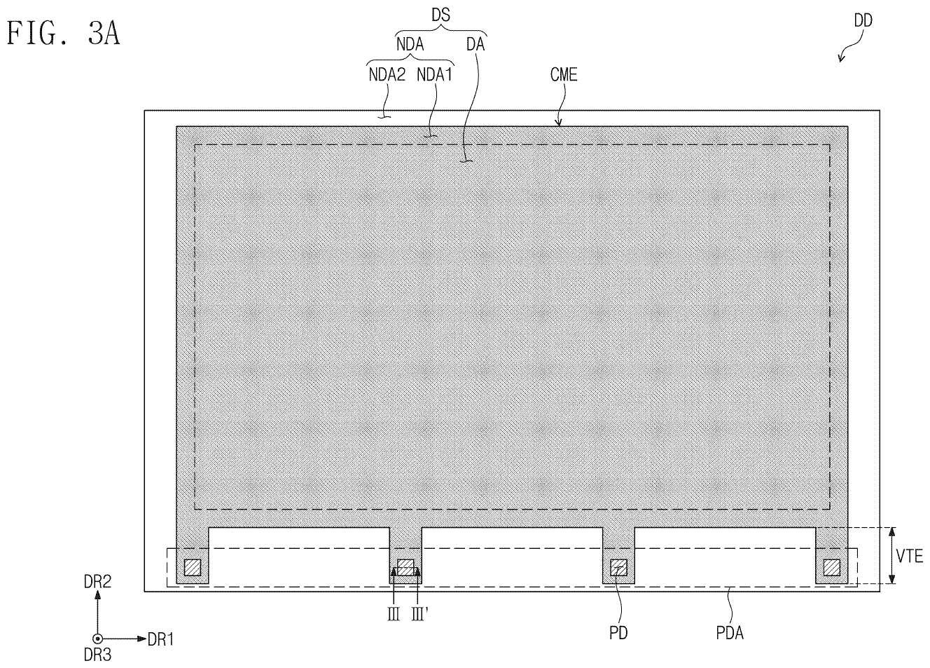

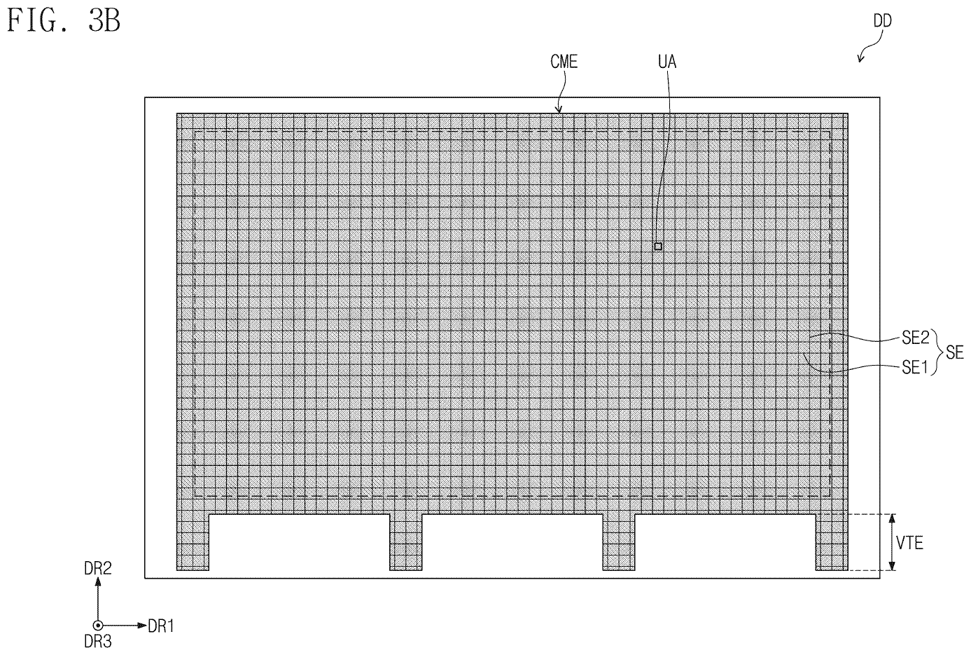

FIG. 3A is a plan view in which a common electrode according to an embodiment of the present disclosure is provided in a display region and a non-display region of a display device. FIG. 3B is a plan view illustrating an arrangement relationship of a voltage transfer electrode, auxiliary electrodes, and a common electrode according to an embodiment of the present disclosure.

A display device DD may include a display region DA and a non-display region NDA. The non-display region NDA may surround the display region DA. The display region DA and the non-display region NDA of the display device DD may be similarly applied to the circuit element layer 10, for example, the CMOS wafer, described with reference to FIG. 2. Hereinafter, the circuit element layer 10 will be described as the CMOS wafer 10, and denoted as the same reference numeral.

Most of a common electrode CME may be provided in the display region DA, and an edge portion of the common electrode CME may be provided in the non-display region NDA. The common electrode CME may transfer a power supply voltage applied from the outside to the entire display region DA.

In this specification, a portion of the non-display region NDA overlapping the edge of the common electrode CME may be defined as a first non-display region NDA1, and another portion of the non-display region NDA other than the first non-display region NDA1 may be defined as a second non-display region NDA2. Accordingly, the second non-display region NDA2 may be a region in which the common electrode CME is not provided.

Dummy light-emitting diodes to be further described herein may be provided in the first non-display region NDA1. The dummy light-emitting diodes may have the same stacked structure as the light-emitting diode of the display region DA, but may not be driven (or may not emit light) because the dummy light-emitting diodes are not electrically connected to the common electrode CME. The structural characteristics of the dummy light-emitting diode will be further described herein.

When forming light-emitting diodes through the same process in a set or particular region, an external region may have a process condition different from that of an internal region. For example, a thickness of a deposited metal layer may be small, and/or an etch rate thereof may be different. Accordingly, a defective light-emitting diode may be formed in the external region, and considering this, a good light-emitting diode is not used but the dummy light-emitting diode is used for the light-emitting diode formed in the external region. When the process condition and the process efficiency are consistent regardless of regions, the dummy light-emitting diode may be omitted, and therefore the first non-display region NDA1 may be omitted in an embodiment of the present disclosure.

A plurality of drive circuits may be provided in the second non-display region NDA2 of the CMOS wafer 10 (see FIG. 2). For example, scan drivers may be respectively provided in a left region and a right region of the second non-display region NDA2 with the display region DA therebetween. A data driver may be provided in a partial region of the second non-display region NDA2 under the display region DA. In embodiments, an analog circuit such as a power supply circuit may be provided in a partial region of the second non-display region NDA2. The aforementioned scan driver, data driver and analog circuit may be embedded in the CMOS wafer. For example, the scan driver, data driver, and analog circuit may include transistors formed through the same method as the pixel circuit.

A pad region PDA in which a plurality of pad electrodes PD are provided may be provided in one side of the second non-display region NDA2. The pad region PDA may correspond to a partial region of the second non-display region NDA2. A circuit board may be connected to the pad region PDA. FIG. 3 illustrates only four pad electrodes PD receiving a power supply voltage applied to the common electrode CME, but more pad electrodes may be provided in the pad region PDA. Pad electrodes may receive a data image signal and/or control signals from the outside and provide the signals to the data driver.

A voltage transfer electrode VTE may be provided in the second non-display region NDA2. Four voltage transfer electrodes VTE corresponding to the four pad electrodes PD are illustrated. The voltage transfer electrode VTE may extend from the common electrode CME toward the pad region PDA. The voltage transfer electrode VTE and the common electrode CME may be formed through the same process, and may have the same stacked structure and have an integrated shape. The voltage transfer electrode VTE and the common electrode CME may correspond to different portions of one electrode which are formed through the same process.

FIG. 3B is a plan view illustrating an arrangement relationship of the voltage transfer electrode VTE, an auxiliary electrode SE, and the common electrode CME according to an embodiment of the present disclosure.

The auxiliary electrode SE may overlap each of the common electrode CME and the voltage transfer electrode VTE. The auxiliary electrode SE may be under the common electrode CME and the voltage transfer electrode VTE in a third direction DR3.

The auxiliary electrode SE may include a plurality of first auxiliary electrodes SE1 extending in a first direction DR1, and a plurality of second auxiliary electrodes SE2 extending in a second direction DR2. The first auxiliary electrodes SE1 may be provided in the second direction DR2, and the second auxiliary electrodes SE2 may be provided in the first direction DR1.

A unit region UA may overlap within a region defined by two first auxiliary electrodes SE1 which are most adjacent to each other along the second direction DR2 among the first auxiliary electrodes SE1, and two second auxiliary electrodes SE2 which are most adjacent to each other along the first direction DR1 among the second auxiliary electrodes SE2.

The unit region UA may be provided within the display region DA in FIG. 3A. One unit region UA is representatively illustrated in FIG. 3B. At least one light-emitting diode may be provided in the unit region UA, and this will be further described in more detail herein.

A portion of the auxiliary electrode SE may overlap the common electrode CME, and the portion overlapping the common electrode CME may be entirely connected to the common electrode CME, thereby reducing a voltage drop that occurs in the common electrode CME. Another portion of the auxiliary electrode SE may overlap the voltage transfer electrode VTE, and the portion overlapping the voltage transfer electrode VTE may be entirely connected to the voltage transfer electrode VTE, thereby lowering the resistance (e.g., electrical resistance) of a voltage transfer path between the pad electrode PD (see FIG. 3A) and the common electrode CME. The auxiliary electrode SE may be formed through the same process regardless of regions, and may have an integrated shape.

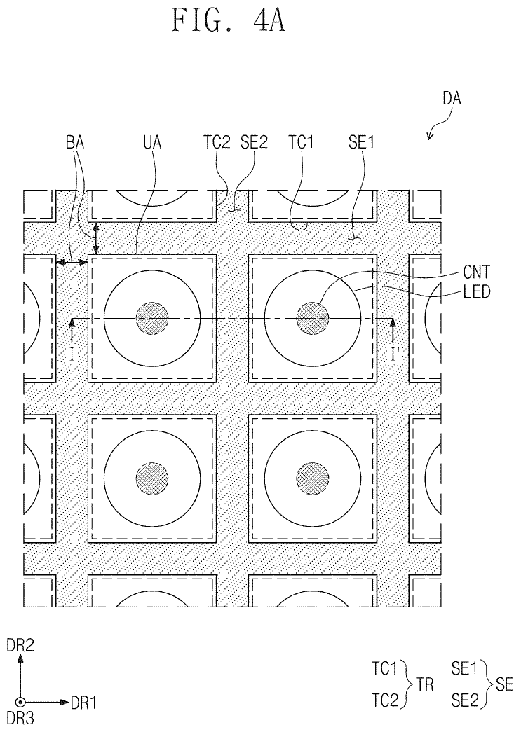

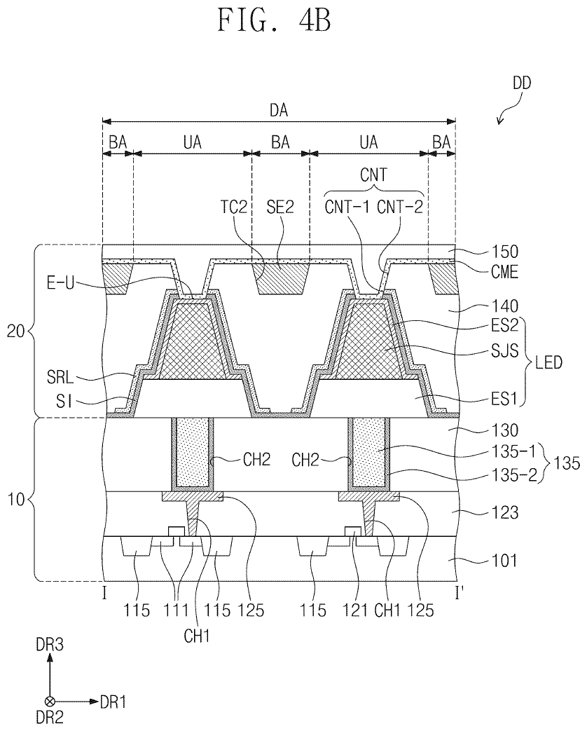

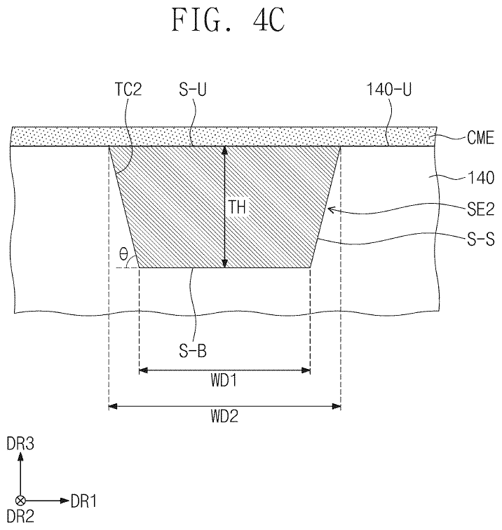

FIG. 4A is an enlarged plan view illustrating a partial region of a display region in FIG. 3A. FIG. 4B is a cross-sectional view taken along line I-I′ of FIG. 4A. FIG. 4C is an enlarged cross-sectional view of a portion of an auxiliary electrode in FIG. 4B.

Referring to FIG. 4A, an auxiliary electrode SE may include first auxiliary electrodes SE1 and second auxiliary electrodes SE2 crossing each other. The auxiliary electrode SE may be provided in a trench TR. The trench TR may include first trenches TC1 and second trenches TC2. The trench TR may be formed by recessing a portion of a planarization layer 140 (see FIG. 4B) to be further described herein in a direction from an upper surface toward a lower surface.

The first auxiliary electrodes SE1 may be respectively provided in the first trenches TC1, and the second auxiliary electrodes SE2 may be respectively provided in the second trenches TC2.

A display region DA may include a plurality of unit regions UA and a boundary region BA between the unit regions UA. Each of the unit regions UA may be an internal region defined by two first trenches TC1 which are adjacent to each other along a second direction DR2 among the first trenches TC1, and two second trenches TC2 which are adjacent to each other along a first direction DR1 among the second trenches TC2. The boundary region BA may be a region in which the first trenches TC1 and the second trenches TC2 are provided. For example, the boundary region BA may correspond to shapes of the first auxiliary electrodes SE1 and the second auxiliary electrodes SE2.

In this embodiment, the boundary region BA is defined as a region in which the first trenches TC1 and the second trenches TC2 are provided, but an embodiment of the present disclosure is not limited thereto. The plurality of unit regions UA may be defined to be narrower than those in FIG. 4A. In embodiments, the width of the boundary region BA may be further increased, and for example, the boundary region BA may be defined to have a width greater than the widths of the first auxiliary electrodes SE1 and the second auxiliary electrodes SE2.

FIG. 4A illustrates light-emitting diodes LED and openings CNT which are provided in the unit regions UA. A common electrode CME in FIG. 4B and the light-emitting diodes LED in FIG. 4B are connected through the openings CNT.

Referring to FIG. 4B, a display device DD may include a CMOS wafer 10 and a light-emitting element layer 20. According to an embodiment, the display device may include a lens layer on the light-emitting element layer 20 and including lenses overlapping the light-emitting diodes LED.

The CMOS wafer 10 includes a silicon substrate 101. A plurality of source or drain regions 111 are defined in the silicon substrate 101. The source or drain regions 111 may each be a region doped with a dopant. The source or drain regions 111 may serve as a source of a transistor or as a drain of a transistor depending on signal flow. One pair of the source or drain regions 111 may define a transistor together with a gate 121 to be further described herein.

Shallow trench isolation (STI) regions 115 may be further defined in the silicon substrate 101. The STI regions 115 may prevent or reduce a leakage current by isolating the transistor. The STI regions 115 may be provided differently depending on a design of a pixel circuit.

The gates 121 are on the silicon substrate 101. The gates 121 may contain metal. The gates 121 are each provided corresponding to one pair of the source or drain regions 111. A first insulation layer 123 is on the silicon substrate 101. The first insulation layer 123 may include an oxide layer such as a silicon oxide layer, a silicon nitride layer, a silicon oxynitride layer, and/or an aluminum oxide layer. It is illustrated that the first insulation layer 123 is a single layer, but the first insulation layer 123 is not limited to the single layer.

The CMOS wafer 10 may include a first contact electrode 125. The first contact electrode may be connected to the source or drain regions 111 through a first contact hole CH1 defined in the first insulation layer 123. An upper surface of the first contact electrode 125 and an upper surface of the first insulation layer 123 may define the same plane (or flat surface). The first contact electrode 125 may be formed thorough a damascene process. The first contact electrode 125 may contain metal such as copper and/or tungsten.

A second insulation layer 130 may be on the first insulation layer 123. A second contact hole CH2 exposing the first contact electrode 125 may be defined in the second insulation layer 130. The second insulation layer 130 may include an oxide layer such as a silicon oxide layer, a silicon nitride layer, a silicon oxynitride layer, and/or an aluminum oxide layer. It is illustrated that the second insulation layer 130 is a single layer, but the second insulation layer 130 is not limited to the single layer.

A second contact electrode 135 may be provided in the second contact hole CH2. An upper surface of the second contact electrode 135 and an upper surface of the second insulation layer 130 may define the same plane (or flat surface). The second contact electrode 135 may include a metal structure 135-1 provided inside the second contact hole, and a barrier layer 135-2 between a side surface of the metal structure 135-1 and an inner surface of the second contact hole CH2, and between a lower surface of the metal structure 135-1 and the upper surface of the first contact electrode 125 exposed through the second contact hole CH2.

The metal structure 135-1 may contain metal such as copper and/or tungsten. The barrier layer 135-2 also has conductivity (e.g., electrical conductivity). The barrier layer 135-2 may increase adhesion between the second insulation layer 130 and the first contact electrode 125, and may prevent or reduce diffusion of metal atoms of the metal structure 135-1 into the second insulation layer 130.

The barrier layer 135-2 may include a barrier metal layer and a barrier metal nitride layer. The barrier metal nitride layer may be provided more adjacent to the second insulation layer 130 than the barrier metal layer. The barrier metal layer increases adhesion, and the barrier metal nitride layer prevents or reduces diffusion of the atoms of the metal structure 135-1. The barrier metal may include titanium and/or tantalum. The barrier layer 135-2 may include a titanium nitride layer and a titanium layer, or may include a tantalum nitride layer and a tantalum layer.

In an embodiment of the present disclosure, the second contact electrode 135 may include a tungsten structure, a titanium layer surrounding a side surface and a lower surface of the tungsten structure, and a titanium nitride layer surrounding the titanium layer. In an embodiment of the present disclosure, the second contact electrode 135 may include a copper structure, a tantalum layer surrounding a side surface and a lower surface of the copper structure, and a tantalum nitride layer surrounding the tantalum layer.

According to an embodiment, the upper surface of the second contact electrode 135 may be concave. A first electrode structure ES1 to be further described herein may be in contact with the concave upper surface of the second contact electrode 135. A shape of the concave upper surface of the second contact electrode 135 may be formed through a damascene process. During chemical mechanical polishing (CMP) of the damascene process, the second contact electrode 135 may be polished more than the second insulation layer 130, so that a dishing phenomenon may occur in the second contact electrode 135.

The light-emitting diode LED may be on the second insulation layer 130. The light-emitting diodes LED according to an embodiment may generate light of the same color. However, an embodiment of the present disclosure is not limited thereto, and one of the four light-emitting diodes LED may generate red color light, another may generate green color light, and still another may generate blue color light. The remaining one may generate one among red, green, blue, and white color light.

The light-emitting diode LED according to an embodiment may include a first electrode, a second electrode, and a light-emitting layer therebetween. In this embodiment, the first electrode is described as the first electrode structure ES1, and the second electrode is described as a second electrode structure ES2. In embodiments, the light-emitting layer includes a semiconductor junction structure SJS.

The light-emitting diode LED according to this embodiment may include the first electrode structure ES1, the semiconductor junction structure SJS on the first electrode structure ES1, and the second electrode structure ES2 on the semiconductor junction structure SJS.

The first electrode structure ES1 may be in contact with the second contact electrode 135, and may have a greater diameter than the semiconductor junction structure SJS. The second electrode structure ES2 may cover at least a portion of an upper surface and/or a side surface of the semiconductor junction structure SJS. However, an embodiment of the present disclosure is not limited thereto, and the second electrode structure ES2 may be on the upper surface of the semiconductor junction structure SJS, and in embodiments, the second electrode structure ES2 may have the same diameter. The present disclosure is not limited to any one embodiment.

As illustrated in FIG. 4A, when the light-emitting diode LED has a circular shape, the first electrode structure ES1 may also have a circular shape. However, the shape of the first electrode structure ES1 is not limited thereto. The first electrode structure ES1 may have an elliptical shape, or may have a polygonal shape such as a square or octagon.

In this embodiment, the first electrode structure ES1 is described as an anode (or anode structure), and the second electrode structure ES2 is described as a cathode (or cathode structure). However, the first electrode structure and the second electrode structure are not limited thereto. In an embodiment of the present disclosure, the first electrode structure ES1 may be a cathode, and the second electrode structure ES2 may be an anode. A stacked structure of the semiconductor junction structure SJS may suitably vary depending on whether the first electrode structure ES1 is an anode or a cathode.

The light-emitting element layer 20 may include a side surface of the first electrode structure ES1, a side surface of the second electrode structure ES2, and a side insulation layer SI on an upper surface of the second electrode structure ES2. The side insulation layer SI may expose a portion E-U of the upper surface of the second electrode structure ES2, and may cover the rest of the second electrode structure ES2 and the side surface of the first electrode structure ES1.

The side insulation layer SI prevents or reduces contact of the light-emitting diode LED with a side reflection layer SRL to be further described herein. The side insulation layer SI may include a silicon oxide layer, a silicon nitride layer, a silicon oxynitride layer, an aluminum oxide layer, a zirconium oxide layer, a hafnium oxide layer, and/or a titanium oxide layer. According to an embodiment, the side insulation layer SI may be provided as a single layer. However, an embodiment of the present disclosure is not limited thereto, and the side insulation layer SI may have a single-layer structure of the aforementioned layers or a multi-layer structure of any layers selected from among the aforementioned layers.

The side reflection layer SRL may be on the side insulation layer SI. The side reflection layer SRL may be provided in plurality, and each of the side reflection layers SRL may cover a portion, of the side insulation layer SI, which overlaps the light-emitting diode LED. The side reflection layers SRL may be spaced apart from each other on the side insulation layer SI. The side reflection layers SRL may be separated and spaced apart from each other in the boundary region BA. However, an embodiment of the present disclosure is not limited thereto, and the side reflection layers SRL may have an integrated shape. For example, the side reflection layers SRL may have an integrated shape within the display region DA in FIG. 4A.

The side reflection layer SRL may increase light efficiency by reflecting light generated from the light-emitting diode LED such that the light generated from the light-emitting diode LED may be emitted. The side reflection layer SRL may include gold (Au), copper (Cu), silver (Ag), titanium (Ti), and/or aluminum (Al).

According to this embodiment, a first contact hole CNT-1 exposing the portion E-U of the upper surface of the second electrode structure ES2 may be defined in the side insulation layer SI and the side reflection layer SRL.

The planarization layer 140 is on the second insulation layer 130. The planarization layer 140 may overlap the plurality of unit regions UA and the boundary region BA, and may cover the light-emitting diodes LED. The planarization layer 140 may include an inorganic material.

A second contact hole CNT-2 overlapping the first contact hole CNT-1 may be defined in the planarization layer 140. The planarization layer 140 may not be on the second electrode structure ES2 within the display region DA. The first contact hole CNT-1 and the second contact hole CNT-2 may overlap each other to define one contact hole CNT, and the contact hole CNT may expose the portion E-U of the upper surface of the second electrode structure ES2.

According to the present disclosure, the planarization layer 140 may fill a region in which the light-emitting diodes LED are not provided. For example, in a portion overlapping the boundary region BA, the planarization layer 140 may be in contact with the side insulation layer SI exposed between the side reflection layers SRL.

As mentioned above, because the first electrode structure ES1 and the semiconductor junction structure SJS have a trapezoidal shape on a cross section, a region between the adjacent light-emitting diodes LED may be formed similarly to a reversed trapezoidal shape.

Accordingly, in the planarization layer 140 covering the light-emitting diodes LED, an upper surface of the planarization layer 140 that fills the region between the adjacent light-emitting diodes LED may be recessed to form the second trenches TC2 with the reversed trapezoidal shape. The above explanation may also be commonly applied to the first trenches TC1 included in the trench TR described with reference to FIG. 4A.

According to the present disclosure, a cross sectional shape of the auxiliary electrode SE provided in the trench TR may result from a shape of the trench TR formed in the region between the adjacent light-emitting diodes LED in the planarization layer 140.

The common electrode CME is on the planarization layer 140. The common electrode CME may overlap the unit regions UA and the boundary region BA. The common electrode CME may include a transparent conductive material so as to emit light generated from the light-emitting diode LED. The common electrode CME may include transparent conductive oxide such as indium tin oxide (ITO), indium zinc oxide (IZO), zinc oxide (ZnO), zinc tin oxide (ZTO), and/or indium gallium zinc oxide (IGZO).

The common electrode CME is connected to the second electrode structures ES2 of the light-emitting diodes LED through the contact holes CNT. A power supply voltage applied through the common electrode CME may be transmitted to the light-emitting diode LED. FIG. 4B illustrates the common electrode CME connected to the two light-emitting diodes LED as an example. One of the two light-emitting diodes LED may be defined as a first light-emitting diode LED and the other one may be defined as a second light-emitting diode LED.

The common electrode CME is in contact with the portion E-U of the upper surface of the second auxiliary electrodes SE2 exposed by the contact holes CNT. The upper surfaces of the second auxiliary electrodes SE2 may be in contact with the common electrode CME along a length direction of the second trench TC2, as illustrated in FIG. 4A, and thus the common electrode CME and the second auxiliary electrodes SE2 may secure a suitable or sufficient contact area therebetween.

A passivation layer 150 is on the common electrode CME. The passivation layer 150 protects the common electrode CME. The passivation layer 150 may overlap the display region DA and the non-display region NDA in FIGS. 3A and 3B, and may protect voltage transfer electrodes VTE. The passivation layer 150 may include an organic material and/or an inorganic material.

According to an embodiment, lenses may be on the passivation layer 150. The lenses condense light emitted from the light-emitting diodes LED. The lenses may include an organic material and may have a hemispherical shape. A diameter of the lenses may be about 1 micrometer or less.

FIG. 4C illustrates an enlarged cross-sectional view of the second auxiliary electrode SE2 provided in the second trench TC2. The explanation regarding the second auxiliary electrode SE2 may also similarly applied to the first auxiliary electrode SE1 described with reference to FIG. 4A.

Referring to FIG. 4C, the second auxiliary electrode SE2 according to an embodiment may include, on a cross section, an upper portion S-U, a lower portion S-B opposed to the upper portion S-U, and a side portion S-S connecting the upper portion S-U and the lower portion S-B. The upper portion S-U may be adjacent to an upper surface 140-U of the planarization layer 140. According to this embodiment, the upper surface 140-U of the planarization layer 140 and an upper surface of the upper portion S-U may define the same plane.

According to this embodiment, the second auxiliary electrode SE2 may have a reversed trapezoidal shape on a cross section. A shape of an internal space of the second trench TC2 may correspond to the shape of the second auxiliary electrode SE2 on a cross section.

A thickness from the upper portion S-U to the lower portion S-B of the second auxiliary electrode SE2, for example, a thickness of the second auxiliary electrode SE2 in a third direction DR3, may be about 0.5 μm to about 1.7 μm.

A first width WD1 of the lower portion S-B in a first direction DR1 may be about 0.3 μm to about 0.7 μm.

A second width WD2 of the upper portion S-U in the first direction DR1 may be about 0.5 μm to about 1.0 μm.

According to an embodiment, an angle θ between the side portion S-S and a virtual line extending from the lower portion S-B may be about 60 degrees to about 89 degrees.

According to the present disclosure, the first and second auxiliary electrodes SE1 and SE2 included in the auxiliary electrode SE may overlap the common electrode CME, and the first and second auxiliary electrodes SE1 and SE2 overlapping the common electrode CME may entirely contact the common electrode CME, thereby reducing a voltage drop that occurs in the common electrode CME. Accordingly, the display device DD having improved quality may be provided.

In embodiments, another portion of the auxiliary electrode SE may overlap the voltage transfer electrode VTE (see FIG. 3A), and the portion overlapping the voltage transfer electrode VTE (see FIG. 3A) may be entirely connected to the voltage transfer electrode VTE (see FIG. 3A), thereby lowering the resistance (e.g., electrical resistance) of a voltage transfer path between the pad electrode PD (see FIG. 3A) and the common electrode CME.

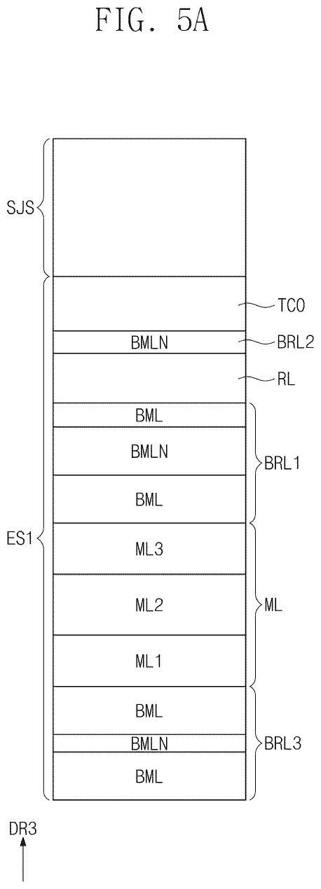

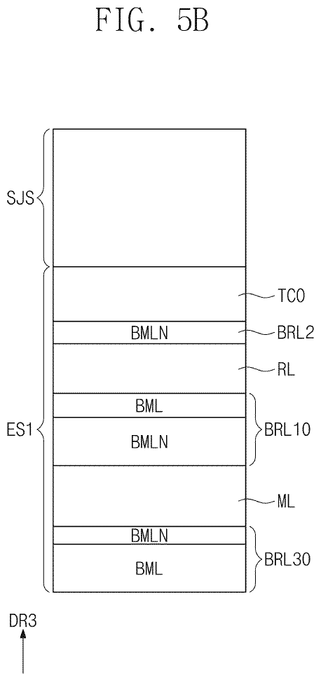

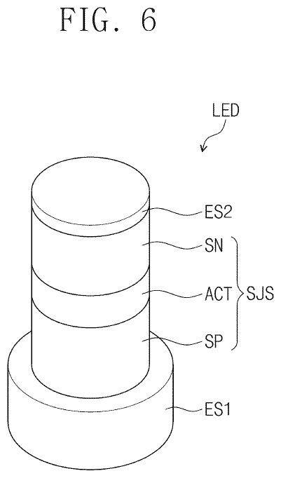

FIGS. 5A and 5B are detailed cross-sectional views illustrating a first electrode structure in FIG. 4B. FIG. 6 is a detailed cross-sectional view illustrating a light-emitting diode in FIG. 4B.

Referring to FIG. 5A, a first electrode structure ES1 may include at least a metal layer ML, a reflection layer RL on the metal layer ML, and a transparent conductive oxide layer TCO (hereinafter, a first transparent conductive oxide layer) on the reflection layer RL. The metal layer ML, the reflection layer RL, and the first transparent conductive oxide layer TCO may be consecutively stacked, or additional functional layers may be further between the metal layer ML, the reflection layer RL, and the first transparent conductive oxide layer TCO.

The metal layer ML corresponds to an adhesive layer for bonding a CMOS wafer and a semiconductor substrate during a process of manufacturing a display device. For example, the metal layer ML may be a layer that is formed by bonding a metal layer of the CMOS wafer and a metal layer of the semiconductor substrate.

The metal layer ML may include at least one metal layer. The at least one metal layer may include any one among gold (Au), copper (Cu), silver (Ag), tin (Sn), titanium (Ti), zirconium (Zr), and tantalum (Ta), and/or may include an alloy of two metals thereof.

In this embodiment, it is illustrated as an example that the metal layer ML has a three-layer structure including first to third metal layers ML1, ML2, and ML3. The second metal layer ML2 may include any one among gold (Au), copper (Cu), silver (Ag), tin (Sn), titanium (Ti), zirconium (Zr), and tantalum (Ta), but may include metal different from those of the first and third metal layers ML1 and ML3. The first and third metal layers ML1 and ML3 may each include any one among gold (Au), copper (Cu), silver (Ag), tin (Sn), titanium (Ti), zirconium (Zr), and tantalum (Ta). In an embodiment of the present disclosure, the metal layer ML may include two consecutive metal layers among the first to third metal layers ML1, ML2, and ML3.

The reflection layer RL may reflect light, which is generated from a semiconductor junction structure SJS, toward the semiconductor junction structure SJS. The reflection layer RL may include gold (Au), copper (Cu), silver (Ag), titanium (Ti), and/or aluminum (Al).

The first transparent conductive oxide layer TCO injects holes into the semiconductor junction structure SJS. The first transparent conductive oxide layer TCO may be advantageous or beneficial for hole injection due to a high work function, and may transmit light reflected from the reflection layer RL. The first transparent conductive oxide layer TCO includes at least one among indium tin oxide (ITO), indium zinc oxide (IZO), zinc oxide (ZnO), zinc tin oxide (ZTO), and indium gallium zinc oxide (IGZO).

In this embodiment, the first electrode structure ES1 is described as an anode and has the aforementioned structure. However, when the first electrode structure ES1 is a cathode, the structure of the first electrode structure ES1 may be changed. An electron injection functional layer and the reflection layer may be integrated into a single metal layer. For example, the metal layer serves as both the electron injection layer and the reflection layer. Accordingly, the cathode structure may include two metal layers which are distinguished from each other.

The first electrode structure ES1 may have a thickness of about 500 nm or less. As the thickness of the first electrode structure ES1 becomes greater, process errors due to the thickness occur. For example, an etch rate may suitably vary depending on the thickness. When the first electrode structure ES1 is thicker, the first electrode structure ES1 is formed to have a more inclined side surface. The first electrode structure ES1 may have a thickness of, for example, about 500 nm or less such that the first electrode structure ES1 is formed to have a vertical side surface.

With reference to FIG. 5A, the first electrode structure ES1 may include a first barrier layer BRL1 between the metal layer ML and the reflection layer RL, a second barrier layer BRL2 between the reflection layer RL and the first transparent conductive oxide layer TCO, and a third barrier layer BRL3 under the metal layer ML. The first to third barrier layers BRL1 to BRL3 may each include a barrier metal layer and a barrier metal nitride layer. The barrier metal layer improves adhesion between adjacent layers, and the barrier metal nitride layer prevents or reduces diffusions of atoms into the adjacent layers.

In this embodiment, the first barrier layer BRL1 may include a barrier metal nitride layer BMLN containing titanium nitride, and barrier metal layers BML containing titanium and respectively on and under the barrier metal nitride layer. For example, a titanium nitride layer may block or reduce migration of metal atoms of the metal layer ML to the reflection layer RL, and may prevent or reduce occurrence of electromigration in the reflection layer RL.

In this embodiment, the second barrier layer BRL2 may include a barrier metal nitride layer BMLN containing titanium nitride. For example, the titanium nitride layer may block or reduce migration of atoms between the first transparent conductive oxide layer TCO and the reflection layer RL, and may prevent or reduce formation of voids in the first transparent conductive oxide layer TCO and/or prevent or reduce oxidation of the reflection layer RL.

In this embodiment, the third barrier layer BRL3 may include a barrier metal nitride layer BMLN containing titanium nitride, and barrier metal layers BML containing titanium and respectively on and under the barrier metal nitride layer. Electromigration occurring between the metal layer ML and the second contact electrode 135 in FIG. 4B may be prevented or reduced.

FIG. 5B illustrates a first electrode structure ES1 of which a stacked structure is simpler than that of FIG. 5A as an example. A metal layer ML may include a single-layer metal layer. A first barrier layer BRL10 may include a barrier metal nitride layer BMLN and a barrier metal layer BML on the barrier metal nitride layer BMLN. A third barrier layer BRL30 may include a barrier metal nitride layer BMLN and a barrier metal layer BML under the barrier metal nitride layer BMLN. The barrier metal nitride layer BMLN of the first barrier layer BRL10 may be in contact with an upper surface of the metal layer ML, and the barrier metal nitride layer BMLN of the third barrier layer BRL30 may be in contact with a lower surface of the metal layer ML.

The stacked structure in FIG. 5B may be formed by making set or certain layers of the stacked structure in FIG. 5A have the same material. For example, when the metal layer ML in FIG. 5A has a single-layer structure of titanium (Ti), and the barrier metal layers BML of the first and third barrier layers BRL1 and BRL3 include titanium (Ti), the metal layer ML and the barrier metal layers BML, of the first and third barrier layers BRL1 and BRL3, which are adjacent to the metal layer ML may constitute a single metal layer.

A light-emitting diode LED is described in more detail with reference to FIG. 6. In FIG. 6, a first electrode structure ES1 is briefly illustrated as a single layer, and a semiconductor junction structure SJS is illustrated in more detail. It is illustrated as an example that the first electrode structure ES1 has a circular disc shape, but the shape of the first electrode structure ES1 is not limited thereto. In this embodiment, the light-emitting diode LED may have a cylindrical shape, but is not limited thereto.

The semiconductor junction structure SJS may include an active layer ACT, a p-type semiconductor layer SP on one side of the active layer ACT, and an n-type semiconductor layer SN on the other side of the active layer ACT. In this embodiment, because the first electrode structure ES1, which is an anode, is under the active layer ACT, the p-type semiconductor layer SP is under the active layer ACT.

The active layer ACT may be formed as a single-quantum well structure or a multi-quantum well structure. Light may be emitted by a combination of electron-hole pairs in response to an electrical signal applied through the p-type semiconductor layer SP and the n-type semiconductor layer SN. The active layer ACT may emit light having a wavelength of about 400 nm to about 900 nm, and may use a double hetero-structure.

In an embodiment of the present disclosure, the active layer ACT may have a structure in which semiconductor materials having high band gap energy and semiconductor materials having low band gap energy are alternately stacked, or may include group III to group V semiconductor materials selected depending on a wavelength range of emitted light.

The p-type semiconductor layer SP may include at least one semiconductor material among InAlGaN, GaN, AlGaN, InGaN, AlN, and InN, and may be doped with a first conductivity-type dopant such as magnesium (Mg), zinc (Zn), calcium (Ca), and/or barium (Ba). For example, the p-type semiconductor layer SP may be p-GaN doped with magnesium (Mg). However, the material that constitutes the p-type semiconductor layer SP is not limited thereto, and in addition thereto, various suitable materials may constitute the p-type semiconductor layer SP.

The n-type semiconductor layer SN may include at least one semiconductor material among InAlGaN, GaN, AlGaN, InGaN, AlN, and InN, and may be doped with a second conductivity-type dopant such as silicon (Si), germanium (Ge), and/or tin (Sn). However, the material that constitutes the n-type semiconductor layer SN is not limited thereto, and in addition thereto, various suitable materials may constitute the n-type semiconductor layer SN.

In embodiments, the light-emitting diode LED may further include a clad layer. The clad layer may be on an upper side and/or on a lower side of the active layer ACT. The clad layer may include an AlGaN layer and/or an InAlGaN layer. The light-emitting diode LED may further include a tensile strain barrier reducing (TSBR) layer on the upper side and/or on the lower side of the active layer ACT. The TSBR layer may be a strain relief layer which is between semiconductor layers having different lattice structures to serve as a buffer so as to reduce a lattice constant difference. The TSBR layer may be composed of a p-type semiconductor layer such as p-GaInP, p-AlInP, and/or p-AlGaInP, but an embodiment of the present disclosure is not limited thereto.

In this embodiment, a second electrode structure ES2 may include a transparent conductive oxide layer (hereinafter, a second transparent conductive oxide layer). The second transparent conductive oxide layer may include indium tin oxide (ITO), indium zinc oxide (IZO), zinc oxide (ZnO), zinc tin oxide (ZTO), and/or indium gallium zinc oxide (IGZO). The second transparent conductive oxide layer may correspond to a protection layer during a process of manufacturing the light-emitting diode LED, and may inject electrons into the semiconductor junction structure SJS. A detailed description of the second transparent conductive oxide layer serving as the protection layer will be provided herein with refence to a manufacturing method.

The second electrode structure ES2 may further include an electrode metal layer between the second transparent conductive oxide layer and the semiconductor junction structure SJS. The electrode metal layer may include metal of which work function is lower than that of the second transparent conductive oxide layer. The electrode metal layer may improve electron injection performance of the second electrode structure ES2. The electrode metal layer may include aluminum (Al), titanium (Ti), indium (In), gold (Au), silver (Ag), nickel (Ni), copper (Cu), an oxide thereof, and/or an alloy thereof.

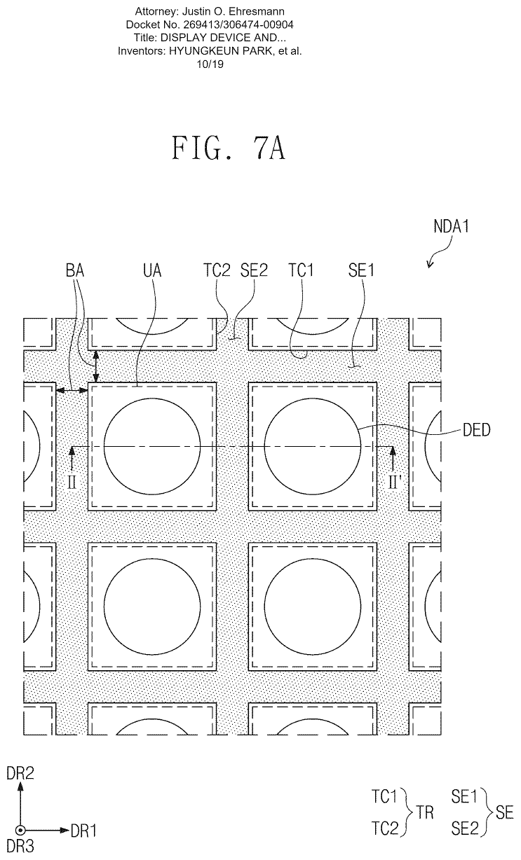

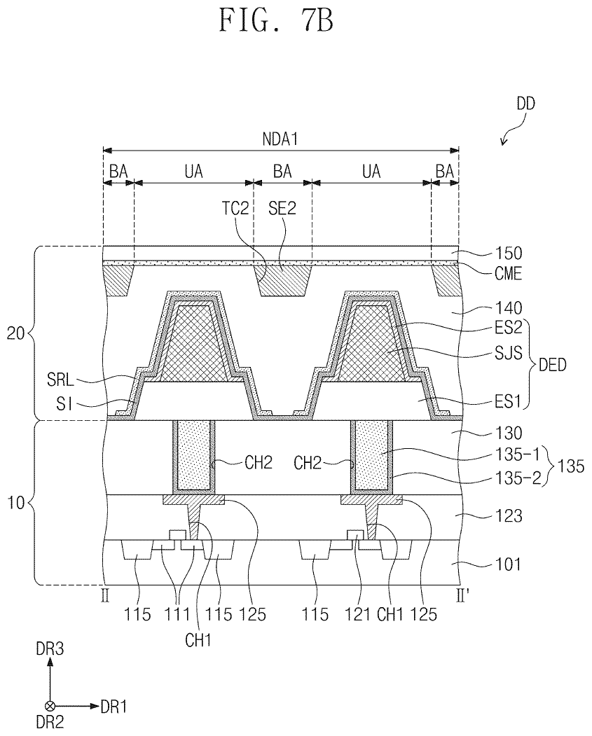

FIG. 7A is an enlarged plan view illustrating a partial region of a non-display region in FIG. 4A. FIG. 7B is a cross-sectional view taken along line II-II′ of FIG. 7A. Referring to FIG. 7A, within a first non-display region NDA1, first auxiliary electrodes SE1 are respectively provided in first trenches TC1 and second auxiliary electrodes SE2 are respectively provided in second trenches TC2. The first auxiliary electrodes SE1 extend from the first auxiliary electrodes SE1 in FIG. 4A, and the second auxiliary electrodes SE2 extend from the second auxiliary electrodes SE2 in FIG. 4A.

The first non-display region NDA1 may include unit regions UA and a boundary region BA between the unit regions UA. Dummy light-emitting diodes DED may be provided in the unit regions UA of the first non-display region NDA1.

The dummy light-emitting diode DED illustrated in FIG. 7B may have substantially the same stacked structure as the light-emitting diode LED illustrated in FIG. 4B. This is because the dummy light-emitting diode DED and the light-emitting diode LED are formed through the same process. A second electrode structure ES2 of the dummy light-emitting diode DED is not exposed to the outside, and is not connected to a common electrode CME. This is because the contact hole CNT (see FIG. 4B) is not formed in a side insulation layer SI, a side reflection layer SRL, and a planarization layer 140. Therefore, the dummy light-emitting diode DED is unable to be driven or emit light.

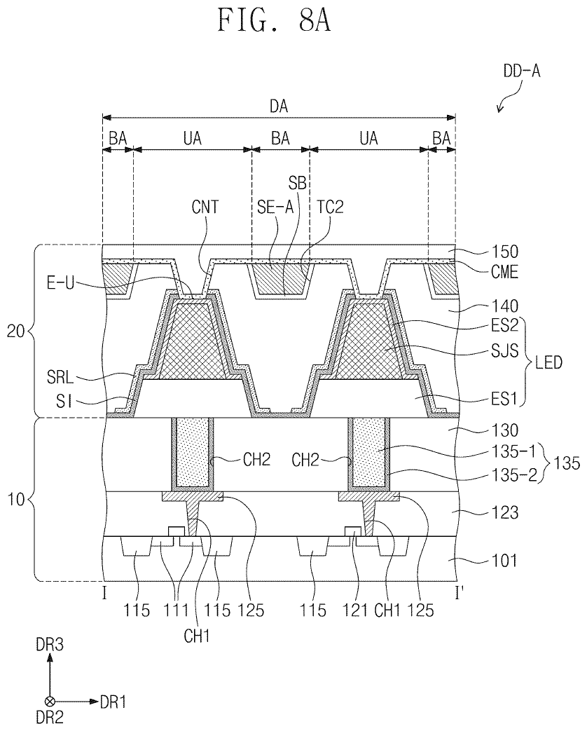

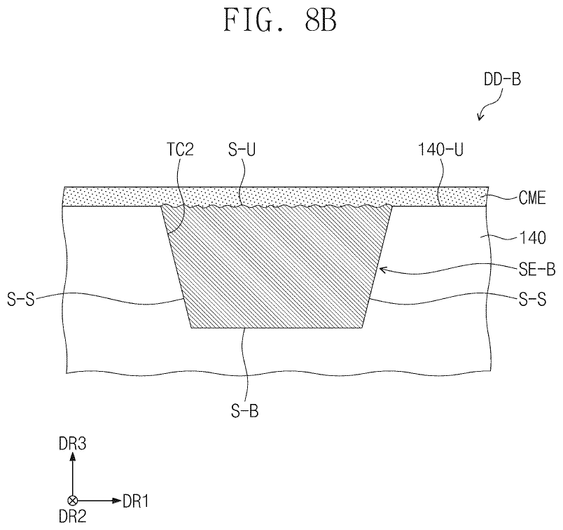

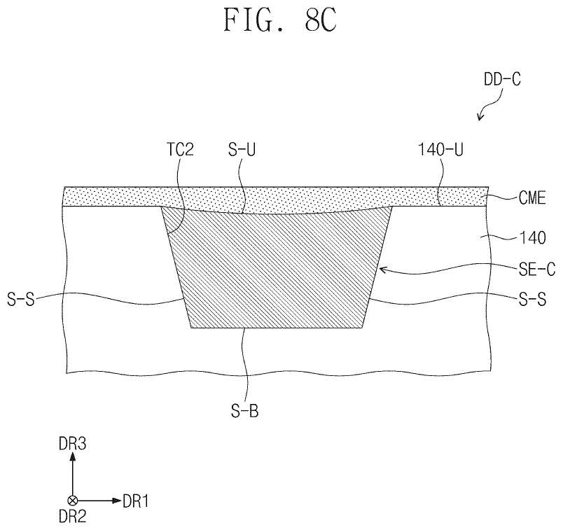

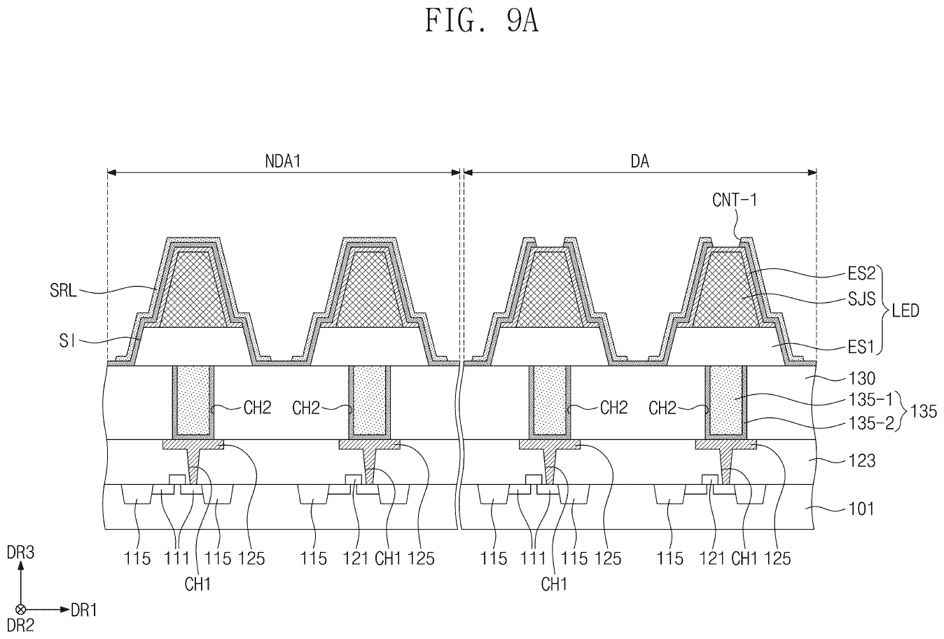

FIG. 8A is a cross-sectional view illustrating a region corresponding to the region in FIG. 4B. FIG. 8B is a cross-sectional view illustrating a portion of an auxiliary electrode according to an embodiment of the present disclosure. FIG. 8C is a cross-sectional view illustrating a portion of an auxiliary electrode according to an embodiment of the present disclosure. Components that are the same as/similar to the components described with reference to FIGS. 1 to 4C will be denoted as the same/similar reference numerals or symbols, and a duplicate explanation thereof may not be repeated here.

Referring to FIG. 8A, a display device DD-A according to an embodiment may include a circuit element layer 10 and a light-emitting element layer 20. The light-emitting element layer 20 may include light-emitting diodes LED and a planarization layer 140 which are on the circuit element layer 10.

The trench TR described with reference to FIG. 4A may be defined in the planarization layer 140. FIG. 8A illustrates second trenches TC2 as an example. The display device DD-A may include auxiliary electrodes SE-A provided inside the second trenches TC2.

According to this embodiment, barrier patterns SB provided inside the second trenches TC2 may be further included. The barrier pattern SB may be provided in the second trenches TC2, and may cover a lower portion and a side portion of the auxiliary electrode SE-A.

The barrier pattern SB has conductivity (e.g., electrical conductivity) like the auxiliary electrode SE-A. The barrier pattern SB may increase adhesion of the auxiliary electrode SE-A to the planarization layer 140, and may prevent or reduce diffusion of metal atoms of the auxiliary electrode SE-A into the planarization layer 140.

The barrier pattern SB may include a barrier metal layer and a barrier metal nitride layer. The barrier metal nitride layer may be provided more adjacent to the planarization layer 140 than the barrier metal layer. The barrier metal layer may include titanium and/or tantalum. The barrier metal nitride layer may include a titanium nitride layer and/or a tantalum nitride layer.

A common electrode CME may be on the planarization layer 140, and a passivation layer 150 may be on the common electrode CME.

FIGS. 8B and 8C illustrate an enlarged view of one part of the region in FIG. 8A in which an auxiliary electrode is provided. Components that are the same as/similar to the components described with reference to FIG. 8A will be denoted as the same/similar reference numerals or symbols, and a duplicate explanation thereof may not be repeated here.

Referring to FIG. 8B, an auxiliary electrode SE-B included in a display device DD-B may be provided in a second trench TC2 defined in a planarization layer 140. The auxiliary electrode SE-B may include an upper portion S-U adjacent to an upper surface of the planarization layer 140, a lower portion S-B opposed to the upper portion S-U, and a side portion S-S connecting the upper portion S-U and the lower portion S-B.

According to this embodiment, the upper portion S-U may have an uneven surface. Because the auxiliary electrode SE-B is formed through chemical mechanical polishing (CMP) of a damascene process, the surface of the upper portion S-U may be formed to be uneven during a polishing process of the auxiliary electrode SE-B.

A common electrode CME may be on the auxiliary electrode SE-B. The common electrode CME may be in contact with the uneven upper portion S-U. According to this embodiment, because the surface of the upper portion S-U has an uneven shape, a contact area between the common electrode CME and the auxiliary electrode SE-B may be increased.

Referring to FIG. 8C, an auxiliary electrode SE-C included in a display device DD-C may be provided in a second trench TC2 defined in a planarization layer 140. The auxiliary electrode SE-C may include an upper portion S-U adjacent to an upper surface of the planarization layer 140, a lower portion S-B opposed to the upper portion S-U, and a side portion S-S connecting the upper portion S-U and the lower portion S-B.

According to this embodiment, the upper portion S-U may have a shape concave in a direction from the upper portion S-U toward the lower portion S-B. Because the auxiliary electrode SE-C is formed through chemical mechanical polishing (CMP) of a damascene process, a surface of the upper portion S-U may be formed to be concave in a direction from the upper portion S-U toward the lower portion S-B during a polishing process of the auxiliary electrode SE-C.

A common electrode CME may be on the auxiliary electrode SE-C. The common electrode CME may be in contact with the concave upper portion S-U. According to this embodiment, because the upper portion S-U has the concave shape, a contact area between the common electrode CME and the auxiliary electrode SE-C may be increased.

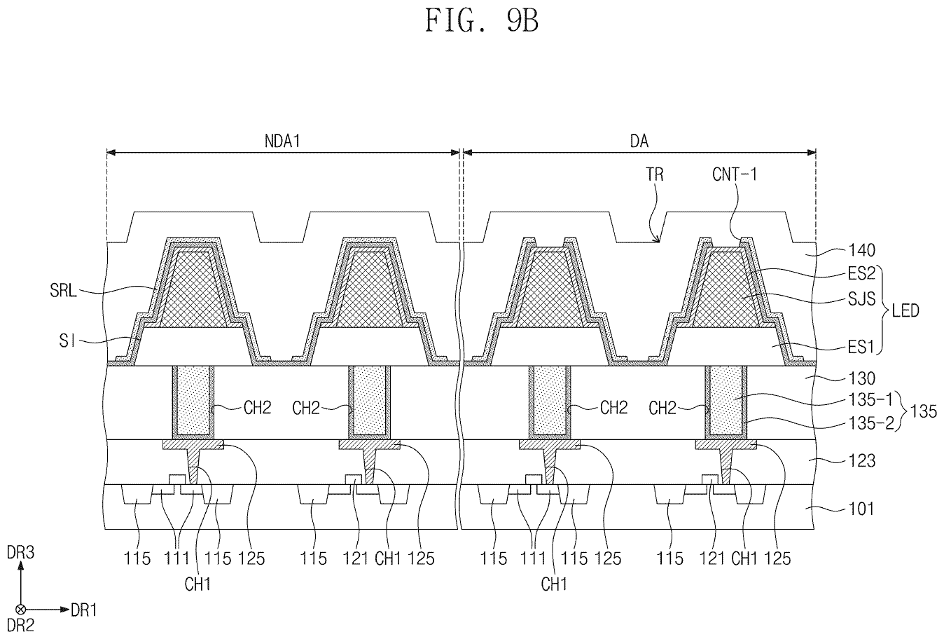

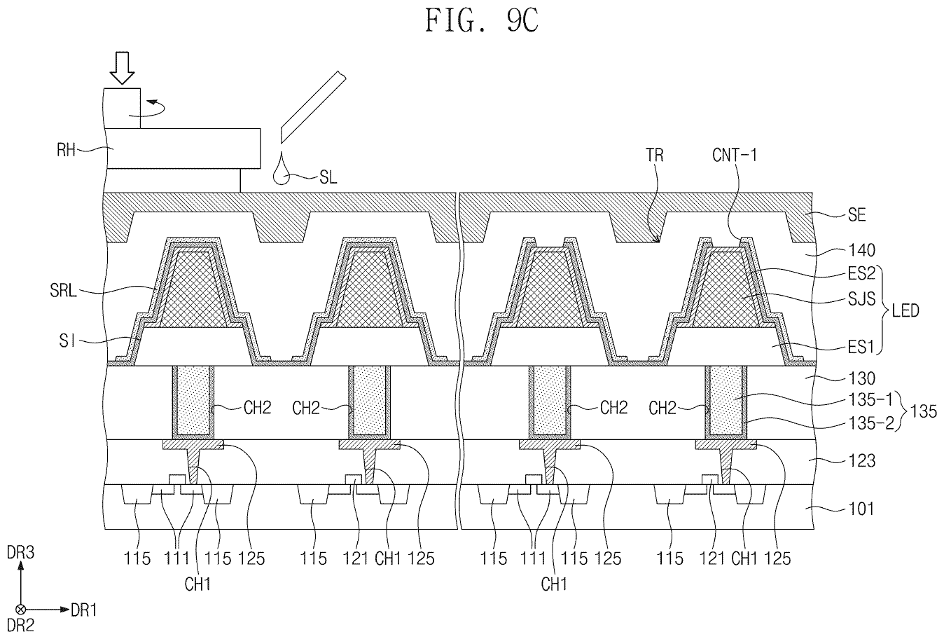

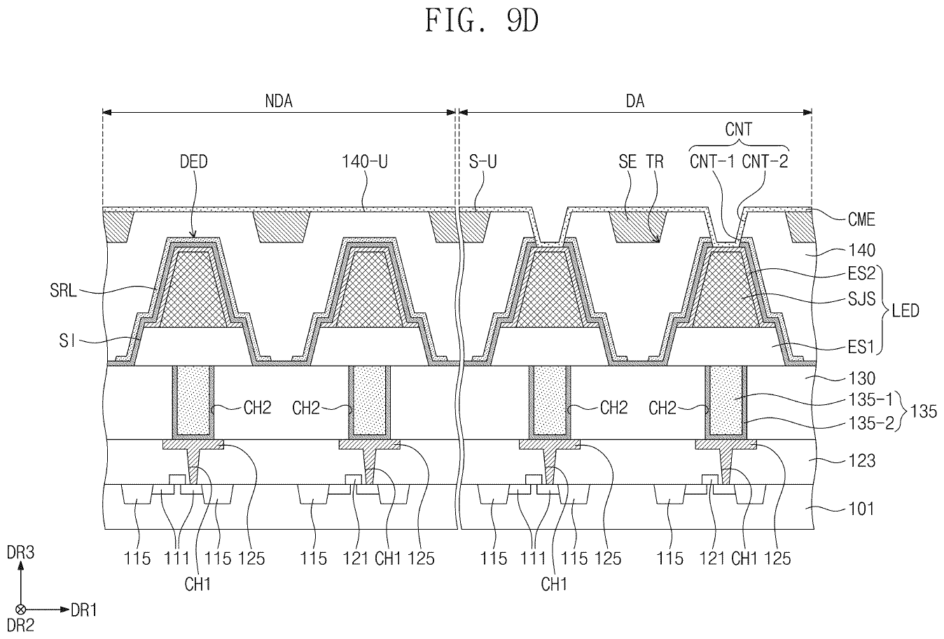

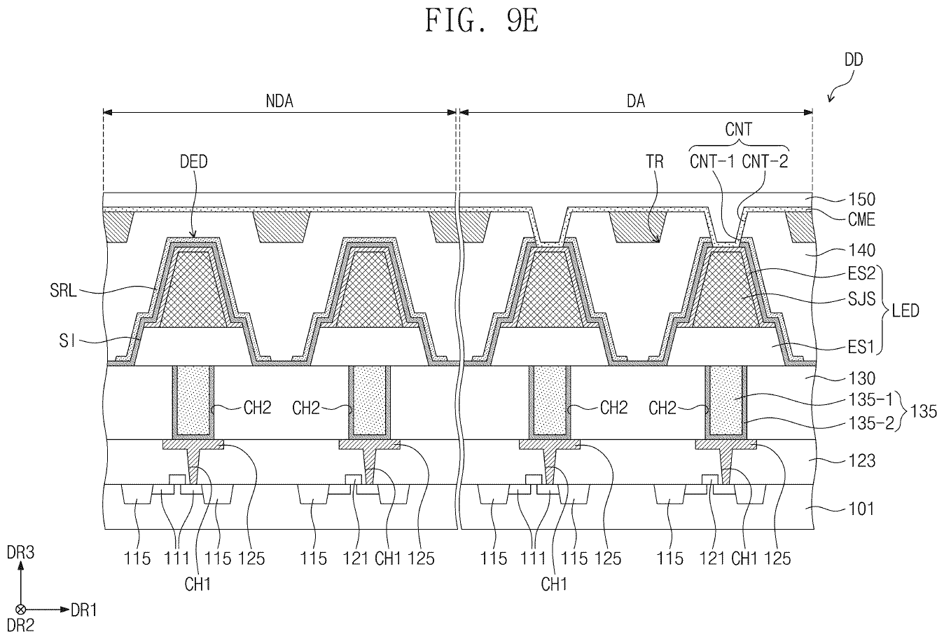

FIGS. 9A to 9E are cross-sectional views illustrating a method of manufacturing a display device according to an embodiment of the present disclosure. Components that are the same as/similar to the components described with reference to FIGS. 1 to 7B will be denoted as the same/similar reference numerals or symbols, and a duplicate explanation thereof may not be repeated here.

Referring to FIG. 9A, a method of manufacturing a display device according to this embodiment may include providing a CMOS wafer. The CMOS wafer may be provided by forming a silicon substrate 101, a first insulation layer 123, and a second insulation layer 130.

Source or drain regions 111 and shallow trench isolation (STI) regions 115 may be formed in the silicon substrate 101. Gates 121 may be formed on the silicon substrate 101. A first contact hole CH1 may be formed in the second insulation layer 130, and a first contact electrode 125 may be formed inside the first contact hole CH1 and connected to the source or drain regions 111 through the first contact hole CH1.

A second contact hole CH2 may be formed in the second insulation layer 130. The second contact hole CH2 may expose the first contact electrode 125. A second contact electrode 135 may be formed in the second contact hole CH2. The second contact electrode 135 may include a metal structure 135-1 provided inside the second contact hole CH2, and a barrier layer 135-2 between a side surface of the metal structure 135-1 and an inner surface of the second contact hole CH2 and between a lower surface of the metal structure 135-1 and an upper surface of the first contact electrode 125 exposed through the second contact hole CH2.

Then, the method may include a step of forming light-emitting diodes LED by forming a conductive layer (e.g., an electrically conductive layer) on the second insulation layer 130 and patterning the conductive layer.

The light-emitting diodes LED may each include a first electrode structure ES1 connected to the second contact electrode 135, a semiconductor junction structure SJS formed on the first electrode structure ES1, and a second electrode structure ES2 formed on the semiconductor junction structure SJS.

Thereafter, a side insulation layer SI covering the light-emitting diodes LED may be formed. The side insulation layer SI may include a silicon oxide layer, a silicon nitride layer, a silicon oxynitride layer, an aluminum oxide layer, a zirconium oxide layer, a hafnium oxide layer, and/or a titanium oxide layer.

Next, side reflection layers SRL which are spaced apart from each other on the side insulation layer SI and which overlap the respective light-emitting diodes LED may be formed. The side reflection layers SRL may each cover a portion, of the side insulation layer SI, which overlaps the light-emitting diode LED. The side reflection layer SRL may include gold (Au), copper (Cu), silver (Ag), titanium (Ti), and/or aluminum (Al).

Afterwards, a first contact hole CNT-1 passing through the side insulation layer SI and the side reflection layer SRL may be formed. The first contact hole CNT-1 may expose an upper surface of the second electrode structure ES2 of the light-emitting diode LED that is formed in a display region DA.

Then, referring to FIG. 9B, a method of manufacturing a display device according to an embodiment may include forming a planarization layer 140. The planarization layer 140 may be formed in the display region DA and a non-display region NDA to cover the light-emitting diodes LED.

According to the present disclosure, the first electrode structure ES1 and the semiconductor junction structure SJS, which are included in each of the light-emitting diodes LED, may have a trapezoidal shape on a cross section. Accordingly, an upper surface of the planarization layer 140 filled between the light-emitting diodes LED that are adjacent to each other along a first direction DR1 may be recessed to have a reversed trapezoidal shape. The recessed portion of the upper surface of the planarization layer 140 may be defined as a trench TR. The trenches TR may be formed in a region between the adjacent light-emitting diodes LED.

Thereafter, referring to FIG. 9C, a method of manufacturing a display device according to an embodiment may include forming an auxiliary electrode SE. At the beginning, the auxiliary electrode SE may be formed in the display region DA and the non-display region NDA.

Subsequently, the method may include polishing the auxiliary electrode SE through a damascene process. Polishing of the auxiliary electrode SE may be performed through chemical mechanical polishing (CMP) of the damascene process. The chemical mechanical polishing (CMP) may polish the auxiliary electrode SE by applying pressure to a rotary polishing machine RH. In embodiments, slurry SL, a type (or kind) of polishing liquid, may be applied so as to prevent or reduce damage to the auxiliary electrode SE.

Afterwards, referring to FIG. 9D, when the process of polishing the auxiliary electrode SE through the chemical mechanical polishing (CMP) is completed, an upper surface 140-U of the planarization 140 and one surface of an upper portion S-U of the auxiliary electrode SE may define the same plane. Substantially, the surface of the upper portion S-U of the auxiliary electrode SE may be uneven due to the chemical mechanical polishing (CMP), or the upper portion S-U may have a shape concave in a thickness direction.

Then, the method may include forming a second contact hole CNT-2 in the planarization layer 140. The second contact hole CNT-2 may overlap the first contact hole CNT-1 and expose a portion of an upper surface of the second electrode structure ES2.

Thereafter, the method may include forming a common electrode CME on the planarization layer 140. The common electrode CME may be in contact with the portion of the upper surface of the second electrode structure ES2 through a contact hole CNT defined in a display region DA.

According to embodiments of the present disclosure, the light-emitting diodes LED, which are formed in a non-display region DNA, among the light-emitting diodes LED may be defined as dummy light-emitting diodes DED. The second electrode structures ES2 included in the dummy light-emitting diodes DED may not be connected to the common electrode CME, and therefore the dummy light-emitting diodes are unable to be driven or emit light.

Referring to FIG. 9E a method of manufacturing a display device according to an embodiment may include forming a passivation layer 150 on the common electrode CME. The passivation layer 150 may include an organic material and/or an inorganic material.

According to one or more embodiments, an electronic device may include the display device, wherein the electronic device may be one selected from among a flat panel display, a curved display, a computer monitor, a medical monitor, a television, a billboard, an indoor light, an outdoor light, a signal light, a head-up display, a fully transparent display, a partially transparent display, a flexible display, a rollable display, a foldable display, a stretchable display, a laser printer, a telephone, a mobile phone, a tablet, a phablet, a personal digital assistant (PDA), a wearable device, a laptop computer, a digital camera, a camcorder, a viewfinder, a micro display, a 3D display, a virtual reality display, an augmented reality display, a vehicle, a video wall including a plurality of displays tiled together, a theater screen, a stadium screen, a phototherapy device, and a signboard.

A display device according to embodiments of the present disclosure may include an auxiliary electrode connected to a common electrode, thereby reducing a voltage drop that occurs in the common electrode.

In the above, description has been made with reference to embodiments, but those skilled in the art or those of ordinary skill in the relevant technical field may understand that various suitable modifications and changes may be made to the subject matter of the present disclosure within the scope not departing from the spirit and the technology scope of the present disclosure described in the appended claims and equivalents thereof.

Therefore, the technical scope of the present disclosure is not limited to the contents described in the detailed description of the specification, but should be determined by the appended claims and equivalents thereof.

What is claimed is:

1. A display device comprising:
a complementary metal-oxide-semiconductor (CMOS) wafer comprising a display region which has unit regions and a boundary region having a grid shape and provided between the unit regions, and a non-display region which is adjacent to the display region;
a light-emitting element layer on the CMOS wafer, and comprising light-emitting diodes that overlap the unit regions and a planarization layer that covers the light-emitting diodes;
an auxiliary electrode connected to light-emitting elements and on the planarization layer; and
a common electrode connected to the auxiliary electrode and on the planarization layer,
wherein the planarization layer comprises a trench which overlaps the boundary region and a portion of which is recessed in a direction from an upper surface of the planarization layer toward the CMOS wafer, and
the auxiliary electrode is provided in the trench and has a reversed trapezoidal shape on a cross section.

2. The display device of claim 1, wherein the auxiliary electrode comprises an upper portion adjacent to the upper surface of the planarization layer, a lower portion opposed to the upper portion, and a side portion that connects the upper portion and the lower portion, and
an angle between the side portion and a virtual line that extends from the lower portion is about 60 degrees to about 89 degrees.

3. The display device of claim 2, wherein a width of the upper portion is about 0.5 μm to about 1.0 μm, and
a width of the lower portion is about 0.3 μm to about 0.7 μm.

4. The display device of claim 2, wherein a thickness from the upper portion to the lower portion is about 0.5 μm to about 1.7 μm.

5. The display device of claim 2, wherein a surface of the upper portion is uneven.

6. The display device of claim 2, wherein the upper portion has a shape which is concave in a direction from the upper portion toward the lower portion.

7. The display device of claim 2, further comprising a barrier pattern provided in the trench and that covers the lower portion and the side portion,
wherein the barrier pattern has conductivity.

8. The display device of claim 1, wherein the light-emitting diodes each comprise:
a first electrode structure on the CMOS wafer and connected to a transistor included in the CMOS wafer;
a light-emitting layer on the first electrode structure; and
a second electrode structure on the light-emitting layer.

9. The display device of claim 8, wherein at least any one of the first electrode structure or the light-emitting layer has a trapezoidal shape on a cross section, and the second electrode structure covers at least a portion of an upper surface or a side surface of the light-emitting layer.

10. The display device of claim 8, wherein the first electrode structure comprises:
a metal layer;
a reflection layer on the metal layer;
a first barrier layer between the metal layer and the reflection layer;
a first transparent conductive oxide layer on the reflection layer; and
a second barrier layer between the reflection layer and the first transparent conductive oxide layer.

11. The display device of claim 10, wherein the metal layer comprises any one among gold (Au), copper (Cu), silver (Ag), tin (Sn), titanium (Ti), zirconium (Zr), and tantalum (Ta), or comprises an alloy of two metals thereof.

12. The display device of claim 10, wherein on a cross section, the auxiliary electrode is between the adjacent first electrode structures.

13. The display device of claim 10, wherein the first barrier layer and the second barrier layer each comprise a barrier metal nitride layer.

14. The display device of claim 10, wherein the first electrode structure further comprises a third barrier layer under the metal layer, and
the third barrier layer comprises titanium nitride or tantalum nitride.

15. The display device of claim 8, wherein the second electrode structure comprises a transparent conductive oxide layer.

16. The display device of claim 8, wherein the CMOS wafer comprises:
a silicon substrate in which source or drain regions are defined;
a gate on the silicon substrate;
a first insulation layer on the silicon substrate and that covers the gate;
a first contact electrode connected to the source or drain regions through a first contact hole defined in the first insulation layer;
a second insulation layer on the first insulation layer and that covers the first contact electrode; and
a second contact electrode connected to a first metal structure and connected to the first contact electrode through a second contact hole that passes through the second insulation layer.

17. The display device of claim 1, further comprising a side insulation layer which covers the light-emitting diodes, and side reflection layers which cover the side insulation layer that overlap the light-emitting diodes and are spaced apart from each other on the side insulation layer.

18. The display device of claim 17, wherein the common electrode is in contact with the light-emitting diode through a contact hole that overlaps the light-emitting diode and that penetrates from the planarization layer to the side reflection layer and the side insulation layer.

19. The display device of claim 18, further comprising a passivation layer on the common electrode,
wherein the passivation layer comprises an inorganic material.

20. An electronic device comprising the display device of claim 1, wherein the electronic device is one selected from among a flat panel display, a curved display, a computer monitor, a medical monitor, a television, a billboard, an indoor light, an outdoor light, a signal light, a head-up display, a fully transparent display, a partially transparent display, a flexible display, a rollable display, a foldable display, a stretchable display, a laser printer, a telephone, a mobile phone, a tablet, a phablet, a personal digital assistant (PDA), a wearable device, a laptop computer, a digital camera, a camcorder, a viewfinder, a micro display, a 3D display, a virtual reality display, an augmented reality display, a vehicle, a video wall including a plurality of displays tiled together, a theater screen, a stadium screen, a phototherapy device, and a signboard.
